(19) United States
(12) Patent Application Publication
(10) Pub. No.: US 2004/0136552 A1
(43) Pub. Date: Jul. 15, 2004

(54) Information handling system earphone storage method and system

(76) Inventors: Rudolf Bendixen, Austin, TX (US); Michael Burchett, Round Rock, TX (US)

Correspondence Address: HAMILTON & TERRILE, LLP, P.O. BOX 203518, AUSTIN, TX, 78720, US

(21) Appl. No.: 10/340,127

(22) Filed: Jan. 10, 2003

(51) Int. Cl. H04R 5/02; G06F 1/16; H05K 5/00; H05K 7/00

(52) U.S. Cl. 381/306; 361/683

(57) ABSTRACT

An earphone storage mechanism integrated in an information handling system stores earphones with an audio output selector that detects the presence or absence of the earphones in order to select earphones or internal speakers of the information handling system to output audible audio information. For instance, upon detecting removal of earphones from an earphone storage opening, the audio output selector switches audible output from internal speakers of a portable information handling system to the earphones. In one embodiment, a cord reel extends and retracts an earphone cord to interface with removably coupled earphones. In another embodiment, a wireless transmitter communicates audio signals to a wireless receiver interfaced with the earphones.

### BACKGROUND OF THE INVENTION

1. Field of the Invention

The present invention relates in general to the field of information handling system audio playback, and more particularly to a method and system for retractable earphones integrated in an information handling system.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Multimedia applications are an increasingly popular use for information handling systems. For instance, video and audio output are presented through an information handling system display and internal speakers or are presented through external peripherals, such as projector and speaker systems. Portable or laptop information handling systems are particularly useful for multimedia applications. For example, a business person traveling for a presentation is able to prepare and practice the presentation on a portable information handling system while traveling and then use the portable information handling system to perform the presentation by interfacing with external peripherals at the presentation site. In addition to business applications, portable information handling systems provide multimedia entertainment, including the presentation of videos, such as DVDs, and music in a convenient and compact system. For instance, while writing a presentation a traveling business person might simultaneously listen to a music CD.

One difficulty with audio output from an information handling system is that the use of internal speakers often is not practical since it disturbs others near the information handling system. For instance, a business traveler on an airplane typically is unable to play audio files over the internal speakers of an information handling system without disturbing other passengers. One alternative for listening to audio files without disturbing other travelers is to listen to the audio files with earphones instead of internal speakers. However, in order for an information handling system user to use earphones, the user generally must carry the earphones as extra equipment that interfaces with an earphone jack or port. In addition to the hassle presented by carrying earphones as extra equipment, the user often must untangle the earphone cords. Further, once the user is finished, the user typically must roll up the earphone cords and store the earphones in a location where the earphones will be available for use when next needed by the user.

### SUMMARY OF THE INVENTION

Therefore a need has arisen for a method and system which conveniently stores and makes available earphones for use with an information handling system.

A further need exists for a method and system which integrates earphones with an information handling system to allow selective replacement of the integrated earphones with other earphones.

In accordance with the present invention, a method and system are provided which substantially reduce the disadvantages and problems associated with previous methods and systems for interfacing earphones with an information handling system. An earphone storage mechanism stores earphones that are operable to output audio signals as audible sounds. An audio output selector interfaced with the earphone storage mechanism selectively interfaces audio signals with earphones under a predetermined condition, such as the presence or absence of the earphones in the earphone storage mechanism.

More specifically, a portable information handling system has electronic information processing components that generate audio information output. One or more speakers of the information handling system generate audible audio output from the audio information output signals. An earphone storage mechanism accepts earphones in earphone storage openings having an audio output selector that detects the insertion or removal of earphones and that selects the speakers for outputting audible audio output if the earphones are inserted in the openings and selects the earphones for outputting audible audio output if the earphones are removed from the openings. The earphone storage mechanism has a reel that extends or retracts earphone cords from within the information handling system. Earphone couplers proximate the end of the earphone cord removably couples earphones to the earphone cord to allow replacement with alternative earphones. In one embodiment, a wireless transmitter associated with the information handling system transmits audio information signals to a wireless receiver associated with the earphones when the earphones are removed from the earphone storage mechanism.

The present invention provides a number of important technical advantages. One example of an important technical advantage is that earphones are conveniently stored and made available for use with an information handling system. Since the earphone storage mechanism is integrated with the information handling system housing, earphones remain conveniently available for use. The earphone cord is extended and retracted with the earphone cord reel so that tangles and other difficulties with cord storage are avoided. Alternatively, a wireless transmission initiated by removal of the earphones from the storage mechanism eliminates the need for the earphone cord.

Another example of an important technical advantage of the present invention is that earphones integrate with an information handling system to allow selective replacement of the integrated earphones with other earphones. Earphone couplers removably couple each earphone to the earphone cord so that alternative or replacement earphones may be integrated with the information handling system, allowing a user to replace original equipment earphones with aftermarket earphones. Alternatively, earphone couplers removably couple each earphone with a wireless receiver so that alternative or replacement earphones may be interfaced with the wireless transmitter of the information handling system.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a side cutaway perspective view of a portable information handling system having integrated earphones; and

FIG. 2 depicts cutaway perspective view of an earphone storage mechanism.

### DETAILED DESCRIPTION

Audible audio output from an information handling system is selectively provided by internal speakers or integrated earphones so that earphones are readily available to a user of an information handling system. For purposes of this application, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

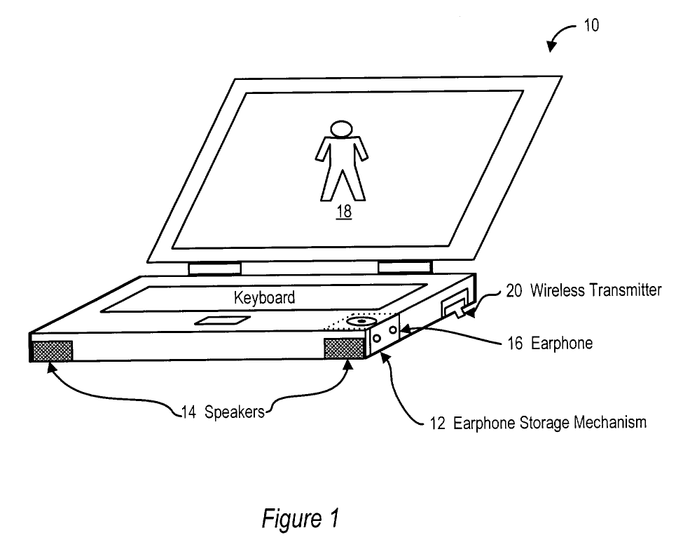

Referring now to FIG. 1, a side cutaway perspective view of a portable information handling system 10 having an integrated earphone storage mechanism 12 is depicted. Portable information handling system 10 outputs audible audio information from internal speakers 14 or integrated earphones 16 depicted in FIG. 1 as retracted and stored in earphone storage mechanism 12. Portable information handling system 10 houses electronic components that generate multimedia signals, such as from video or audio files, for presentation of video information on display 18 and output of audio information from speakers 14 or earphones 16. Earphone storage mechanism 12 detects the insertion and storage of earphones 16 to select output of audio information from speakers 14 and detects the removal of earphones 16 to select output of audio information from earphones 16. In one embodiment, audio signals are transmitted to earphones 16 through a wireless transmitter 20, such as an 802.11b standard transmitter, and converted to audio output by a wireless receiver associated with earphones 16. In another embodiment, audio signals are transmitted to earphones 16 through an earphone cord retracted into and extended from earphone storage mechanism 12.

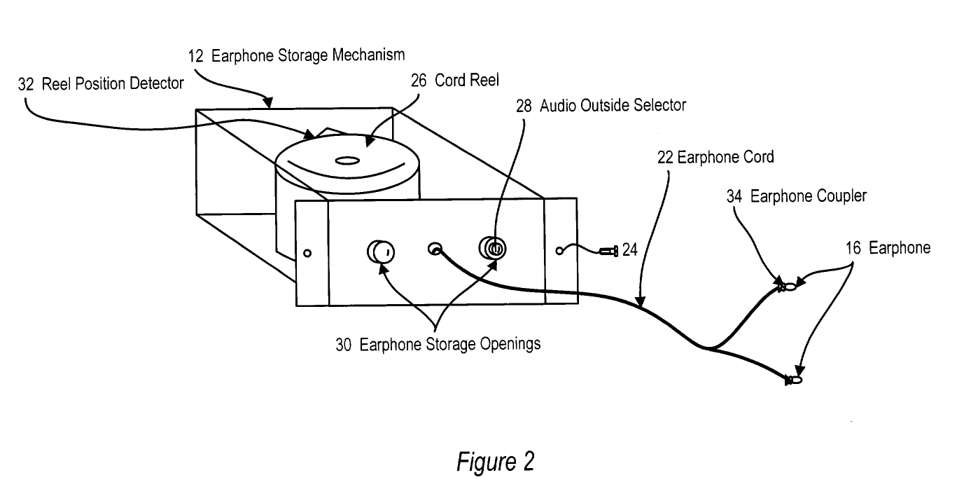

Referring now to FIG. 2, a perspective cutaway view of earphone storage mechanism 12 configured to store an earphone cord 22 is depicted. Earphone storage mechanism 12 integrates within portable information handling system 10 by, for instance, coupling a screw 24 into portable information handling system 10 and interfacing earphone cord 22 with electronic components of portable information handling system 10 that generate audio signals. Earphone cord 22 is stored by retraction into an internal earphone cord reel 26 that has a spring bias to retract earphone cord 22. Earphone cord 22 is extended from earphone cord reel 26 by pulling on earphone cord 22 and is maintained in the extended position by an internal detent that is released by a tug on earphone cord 22. Thus, cord reel 26 stores earphone cord 22 internally within portable information handling system 10 in a manner that makes earphones 16 readily and conveniently available for use to selectively output audio information.

Selection of speakers 14 or earphones 16 to output audio information is accomplished with an audio output selector 28 disposed within an earphone storage opening 30. Earphone storage openings 30 are sized and shaped to securely accept earphones 16 in a removable manner, such as with a clip spring or other securing device. When an earphone 16 is inserted in an earphone storage opening 30, audio output selector 28 is depressed to switch to audio output from speakers 14. When an earphone 16 is removed from an earphone storage opening 30, audio output selector 28 is released to switch to audio output from earphones 16. In an alternative embodiment, a reel position detector 32 determines whether earphones 16 are retracted or extended based on the position of cord reel 26 and selects audio output from speakers 14 if a predetermined amount of earphone cord 22 is extended or selects audio output from earphones 16 if less than the predetermined amount of earphone cord 22 is extended.

Integrated earphones stored in an integrated earphone storage mechanism 16 improve the convenience of listening to audio output from an information handling system. In order to allow greater user flexibility in the selection of earphones 16 by a user of portable information handling system 10, an earphone coupler 34 removably interfaces earphones 16 with earphone cord 22. For instance, earphone couplers 34 are jacks or plugs that couple with earphones 16 to communicate audio signals to earphones 16 and that release earphones 16 to allow replacement with alternative earphones, for instance including replacements of failed earphones or alternative earphones having a desired user quality. Earphone coupler 34 is proximate earphone 16 to reduce interference of earphone coupler 34 with storage and retraction of earphone cord 22, however, earphone coupler may be located along the length of earphone cord 22. In an alternative embodiment, earphones 16 are replaced with other earphones by replacement of cord reel 26 or earphone storage mechanism 12 with a different earphone cord and earphone set. Replacement of wireless earphones is performed by interfacing the replacement earphones with the wireless receiver.

Although the present invention has been described in detail, it should be understood that various changes, substitutions and alterations can be made hereto without departing from the spirit and scope of the invention as defined by the appended claims.

What is claimed is:

1. An information handling system comprising:
a housing;
electronic components disposed in the housing and operable to generate audio information output;
one or more speakers disposed in the housing and operable to generate audible audio output from the audio information;
a cord reel integrated in the housing and operable to retract and extend a cord;
an earphone cord interfaced with the electronic components and with the cord reel;
earphones interfaced with the earphone cord and operable to generate audible audio output from the audio information; and
an audio output selector interfaced with the cord reel and operable to select the speakers to generate audible output if the earphones cord is retracted in the cord reel and to select the earphones to generate audible output if the earphone cord is extended from the cord reel.

2. The information handling system of claim 1 further comprising earphone storage openings integrated with housing and operable to store the earphones.

3. The information handling system of claim 2 wherein the audio output selector interfaces with an earphone storage opening to select the speakers to generate audible output if an earphone is stored in the storage opening and to select the earphones to generate audible output if no earphone is stored in the storage opening.

4. The information handling system of claim 1 wherein the cord reel is further operable to rotate between a retracted position and an extended position and the audio output selector is further operable to determine that the earphones are extended if the cord reel is in an extended position or that the earphones are retracted if the cord reel is in a retracted position.

5. The information handling system of claim 1 further comprising earphone couplers associated with the earphone cord and operable to release the earphones from the earphone cord.

6. The information handling system of claim 5 wherein the earphone couplers are further operable to couple replacement earphones to the earphone cord.

7. The information handling system of claim 5 wherein the earphone couplers are proximate one end of the earphone cord to couple directly with the earphones.

8. A method for selectively outputting audible information from an information handling system, the method comprising:
integrating retractable earphones in an information handling system housing;
determining whether the earphones are retracted in a stored position within the information handling system housing or extended from the information handling system housing;
outputting audible information from speakers of the information handling system if the earphones are retracted in the stored position within the information handling system housing; and
outputting audible information from the earphones if the earphones are extended from the information handling system housing.

9. The method of claim 8 wherein determining whether the earphones are retracted or extended further comprises determining that the earphones are retracted if the earphones are secured in earphone storage openings integrated with the housing and determining that the earphones are extended if the earphones are absent from the earphone storage openings.

10. The method of claim 9 further comprising interfacing the earphones with the information handling system with an earphone cord, and wherein determining whether the earphones are retracted or extended further comprises measuring the amount of earphone cord extended from the housing.

11. The method of claim 10 wherein measuring further comprises measuring the position of a reel that stores earphone cord.

12. The method of claim 9 further comprising interfacing the earphones with the information handling system with a wireless communication signal.

13. The method of claim 8 further comprising:
interfacing the earphones with the information handling system through an earphone cord;
removing the earphones from the earphone cord; and
replacing the earphones with alternative earphones.

14. The method of claim 8 further comprising:
interfacing the earphones with the information handling system through an earphone cord;
removing the earphone cord from the information handling system; and
replacing the earphone cord with an alternative earphone cord having alternative earphones.

15. The method of claim 14 further comprising storing the earphone cord on a reel integrated in the information handling system housing, and wherein replacing the earphone cord further comprises replacing the reel.

16. A portable information handling system comprising:
a portable housing having information processing components operable to output audio signals;
earphones operable to output the audio signals as audible sounds;
an earphone storage mechanism integrated with the portable housing and operable to store the earphones; and
an audio output selector interfaced with the earphone storage mechanism and operable to selectively interface the audio signals to the earphones under a predetermined condition.

17. The portable information handling system of claim 16 wherein the predetermined condition comprises removal of the earphones from the earphone storage mechanism.

18. The portable information handling system of claim 16 wherein the earphone storage mechanism comprises a reel operable to extend and retract an earphone cord interfaced with the earphones.

19. The portable information handling system of claim 16 wherein the information processing components further comprise a wireless transmitter operable to transmit the audio signals and wherein the earphones further comprise a wireless receiver operable to receive the audio signals.

20. The portable information handling system of claim 16 wherein the earphone storage mechanism comprises an opening integrated with the portable housing operable to secure the earphones and wherein the audio output selector comprises a switch proximate the opening and operable to detect the presence or absence of earphones in the opening.
